(19) United States
(12) Patent Application Publication
(10) Pub. No.: US 2004/0238901 A1
(43) Pub. Date: Dec. 2, 2004

(54) Electronic device and composition

(76) Inventors: Abraham Rudolf Balkenende, Eindhoven (NL); Femke Karina De Theije, Eindhoven (NL); Jan Cornelis Kriege, Eindhoven (NL)

Correspondence Address: PHILIPS ELECTRONICS NORTH AMERICA CORPORATION, INTELLECTUAL PROPERTY & STANDARDS, 1109 MCKAY DRIVE, M/S-41SJ, SAN JOSE, CA, 95131, US

(21) Appl. No.: 10/489,049

(22) PCT Filed: Sep. 12, 2002
(86) PCT No.: PCT/IB02/03787

(30) Foreign Application Priority Data
Sep. 17, 2001 (EP) 01203536.6
Mar. 28, 2002 (EP) 02076262.1

(51) Int. Cl. H01L 29/76

(52) U.S. Cl. 257/406

(57) ABSTRACT

The electronic device with a layer of mesoporous silica can be obtained by applying a composition comprising alkoxysilane, a surfactant and a solvent onto a substrate, and by subsequently removing the surfactant and the solvent. The customary dehydroxylation treatment is not necessary if the composition contains a mixture of tetra-alkoxysilane, particularly teatraethoxyorthosilicate (TEOS), and an alkyl-substituted alkoxysilane, particularly a phenyl-substituted, methyl-substituted or ethyl-substituted trialkoxysilane. If both silanes are present in a molar ratio of approximately 1:1, a layer with a dielectric constant of 2.5 or less is obtained.

The invention relates to an electronic device comprising a substrate provided on one side with a mesoporous layer containing silica, which can be obtained by, inter alia, applying a layer of a composition comprising a tetra-alkoxysilane, an alkyl-substituted alkoxysilane, a surfactant and a solvent, and by removing the solvent and the surfactant, thereby forming the mesoporous layer.

The invention also relates to a composition comprising tetra-alkoxysilane, aryl-substituted or alkyl-substituted alkoxysilane and a solvent.

The invention further relates to a method of preparing a mesoporous layer comprising the application of a liquid layer of a composition containing tetra-alkoxysilane, aryl-substituted or alkyl-substituted alkoxysilane, a surfactant and a solvent onto a substrate, and removing the surfactant and the solvent from the liquid layer, thereby forming the hydrophobic, mesoporous layer.

Such an electronic device is known from WO-A 00/39028. Example 5 discloses a composition comprising tetraethoxyorthosilicate and methyltriethoxysilane. Said tetraethoxyorthosilicate, also referred to as TEOS, is a frequently used tetra-alkoxysilane. Tetra-alkoxysilanes will hereinafter also be referred to as TEOS. Methyltriethoxysilane, also referred to as MTES, is an example of an aryl-substituted or alkyl-substituted alkoxysilane. A further example thereof is methyltrimethoxysilane, also referred to as MTMS. Such aryl-substituted or alkyl-substituted alkoxysilanes will hereinafter also be referred to as ASAS.

The known composition comprises TEOS and MTES in a ratio of 0.85:0.15. For the surfactant use is made of 10 lauryl ether, also referred as C₁₂H₂₅(CH₂CH₂O)₁₀OH. The solvent is a 50/50 mixture of water and ethanol. Furthermore, hydrogen chloride is used as the catalyst. The surfactant:silane:water:ethanol:hydrogen chloride ratio is 0.17:1:5:5:0.05. After ageing for 20 hours, this composition is applied to silicon slices by means of spin coating at 2000 rpm for 30 seconds. The solvent and the acid are removed in 1 hour at 115 ° C., after which the surfactant is completely removed by calcination at 475 ° C. for 5 hours. Finally, a dehydroxylation, process takes place by exposing the mesoporous layer to a silane, such as a 10% solution of hexamethyldisilazane in toluene, and subsequently to a vacuum treatment, which dehydroxylation process is repeated a number of times at temperatures in the range between 25 and 450 ° C. The resulting layer may be present in a semiconductor device, in particular as a dielectric between two conductors in an interconnect structure, on account of the low dielectric constant. The relative dielectric constant, in relation to the dielectric constant of a vacuum, is 2.25.

A drawback of the known electronic device resides in that a dehydroxylation aftertreatment is required. Said aftertreatment renders the mesoporous layer hydrophobic, however, it is by no means a certainty that the layer becomes completely hydrophobic. Moreover, it is possible that subsequent steps in the manufacturing process annihilate the results of the aftertreatment. Besides, said aftertreatment involves at least one additional step in the manufacturing process.

Therefore, it is a first object of the invention to provide an electronic device of the type mentioned in the opening paragraph, by means of which a stable, mesoporous layer can be obtained without a dehydroxylation aftertreatment.

The first object is achieved in that TEOS and ASAS are present in a molar ratio of 3:1 at the most.

By using a composition comprising a mixture of TEOS and one or more aryl-substituted or alkyl-substituted alkoxysilanes, a stable layer is obtained that does not require a dehydroxylation aftertreatment. The invention is based on the recognition that the formation of a silica network from the alkoxysilanes requires less than four alkoxy groups per silicon atom. Any remaining alkoxy groups and the silanol groups formed after hydrolysis render the silica network hydrophilic. In relation to TEOS, ASAS contains fewer alkoxy groups. On the other hand, ASAS comprises more hydrophobic aryl or alkyl groups. These alkyl groups have a hydrophobic, apolar character and preclude water adsorption in the porous silica network.

The solvent and the surfactant are preferably removed in a treatment at an increased temperature. The increased temperature is in the range of about 150 to 500 ° C. The treatment wherein solvent and surfactant are removed and a polysilicate coating is formed, is per se known as sol-gel processing.

The hydrophobic character of the mesoporous layer in the device in accordance with the invention implies that essentially no water adsorption takes place up to an air humidity degree of approximately 50%. This is sufficient in actual practice since the air humidity degree in clean rooms can be maintained between 40 and 50%. The device may be exposed to a higher degree of air humidity during operation, however, an electronic device is customarily encapsulated in a layer to protect it against moisture. With a decreasing ratio of tetra-alkoxysilane to aryl-substituted or alkyl-substituted alkoxysilane the sensitivity to air humidity decreases until the layers are completely insensitive to air humidity. It has been found that layers that can be obtained using a composition comprising TEOS and ASAS in a molar ratio above 3:2 are insensitive to air humidity. Preferably the molar ratio is below 1:3, which provides an excellent mechanical stability.

Although it is stated in the prior art that compositions have been prepared wherein the molar ratio between TEOS and ASAS is below 5:1, the prior art does not comprise measuring results to substantiate this. Besides, a dehydroxylation step has been carried out. The conclusion drawn from that is that the result obtained by means of the invention was not achieved in the prior art.

From the article “Synthesis of ordered mesoporous organic-inorganic thin films” by Balkenende et al, Book of Abstracts, Conference on nanostructured materials made from self-assembled molecules and particles, Hindas (Sweden), 2001, a composition is known with a molar ratio between tetra-alkoxysilane and methyltriethoxysilane of 1:3 and 1:1. The layers formed are subjected to an aftertreatment at a temperature in the range from 350 to 800 ° C. However, for persons skilled in the art there is no reason to believe that, without a dehydroxylation aftertreatment, a mesoporous layer can be obtained exhibiting hardly any water adsorption at air humidity degrees up to 50% or higher.

In a first embodiment of the device in accordance with the invention, the mesoporous layer is a transmission layer. Said transmission layer may be part of an interference filter. The stability up to high humidity levels and the low refractive index enable a desired filtering characteristic to be efficiently realized. The transmission layer can also be used in display devices, such as at the surface of CCDs and LCDs, and in field-emission displays. For this reason, it is desirable for the molar ratio between TEOS and ASAS to be below 3:2. At said ratio, a mesoporous layer having a very low refractive index is obtained, which is not dependent on the air humidity. Using MTMS as the ASAS, at said molar ratios and porosity levels above 50%, refractive indices between 1.15 and 1.22 are obtained.

In a second embodiment of the device in accordance with the invention, a first and a second conductor are present which are electrically insulated from each other by the mesoporous layer having, in this embodiment, a relative dielectric constant below 3.0. An example thereof is a semiconductor device comprising the mesoporous layer as an intermetallic or intrametallic dielectric. The conductors may be present in different layers on the substrate. It is alternatively possible for the conductors to be situated in the same layer where they are laterally separated from each other. Another example is a network of passive components. Such a network is known from, for example, PCT-application WO-A 01/61847. In this case, the mesoporous layer is applied to separate a first and a second winding of a coil from each other. Such a network can of course also be integrated in an interconnect structure of a semiconductor device. The device may alternatively be a bulk-acoustic wave resonator. Such a device is known from patent application EP-A-1067685. Furthermore, the mesoporous layer may be situated directly on the substrate or in the substrate so as to form a buried oxide. In this manner, electrical losses to the substrate can be reduced substantially. The applications WO-A 01/61847 and EP-A-1067685 are incorporated in this application by reference.

A first advantage of the electronic device in accordance with the invention resides in that a layer is obtained having a uniform pore size below 10 nm. By virtue of said pore size, the layer can suitably be used in an integrated circuit having a very high resolution up to, for example, 70 or 100 nm. If at least part of the pores would be larger than several nanometers, a barrier layer of, for example, TaN to be applied to the mesoporous layer can no longer be provided so as to cover the entire mesoporous layer. As a result of the fact that this barrier layer is not tight, impurities in the form of Cu ions (in the case of Cu metallization) can disturb the properties of the layer or the device. If the size of the pores is of the order of the distance between the metal lines, short-circuits may occur between a first and a second conductor on either side of the mesoporous layer.

It is particularly preferred to provide a mesoporous layer with pore sizes below 8 or even below 5 nm. Such layers can be for instance obtained with the use of a surfactant as cetyltrimethylammoniumbromide (CTAB). On such a mesoporous layer a barrier layer with a thickness below 10 nm can be applied with success, for instance with Atomic Layer Chemical Vapour Deposition (ALCVD). The resulting stack of mesoporous layer and barrier layer, wherein the mesoporous layer is etched according to desired pattern, is suitable for damascene processing, as known per se to the skilled person.

A second advantage of the electronic device in accordance with the invention resides in that the mechanical properties of the mesoporous layer are better than those of other types of known mesoporous layers. From S. Yang et al., Chem. Mater. 14(2002), 369-374, for example, a mesoporous layer of poly(methylsilsesquioxane) or MSQ is known having porosities ranging from 30 to 50% and hardness levels of 0.28 GPa at a porosity of 40% and 0.16 GPa at a porosity of 50%. The mesoporous layer in accordance with the invention, however, enables hardness levels of 0.6-0.8 GPa to be obtained at porosity levels between 40 and 45%, and a hardness of 0.5 Pa at porosity levels between 52 and 60%.

In a favorable embodiment of the electronic device in accordance with the invention, the mesoporous layer has a porosity above 45%. These higher porosity levels are obtained by increasing the surfactant content in the composition. It has surprisingly been found that the stability of the mesoporous layer in accordance with the invention remains good at higher surfactant contents. In the method in accordance with the prior art, however, a larger amount of surfactant causes the layer formed to become unstable after calcination. Said unstability means that the network of porous silica collapses, causing the porosity to decrease substantially from 55 to 28%. The advantage of a higher porosity is, in particular, that a lower dielectric constant is obtained. A relative dielectric constant of 1.7 has been achieved.

Favorable effects are achieved by using an alkyl- or aryl-substituted alkoxysilane wherein the alkyl respectively aryl group is selected among a methyl group, an ethyl group and a phenyl group, or wherein the alkyl group is fluoridized. Such phenyl-substituted, methyl-substituted and ethyl-substituted alkoxysilanes are thermally stable up to approximately 450° C., allowing them to be calcined in the customary manner. Preferably the alkoxy group is a butoxy, propoxy, ethoxy or methoxy group. Said thermal stability is particularly favorable for semiconductor devices which are subjected to a heating step at approximately 400° C. before the encapsulation is provided.

The alkyl- or aryl-substituted alkoxysilane may additionally be a trialkylalkoxysilane, a dialkyldialkoxysilane and an alkyltrialkoxysilane or aryl-substituted analogues. Particularly favorable examples are methyltrimethoxysilane, methyltriethoxysilane, phenyltrimethoxysilane, phenyltriethoxysilane. What is meant here is that, by virtue of the crosslinking of the three alkoxy groups, such alkyltrialkoxysilanes can be integrated very readily in the silica network, and that, for this reason, the stability of the network decreases hardly, if at all, in relation to a network of pure TEOS.

Particularly favorable results are obtained by using a composition comprising TEOS and an ASAS, in particular MTMS, in a molar ratio below 3:2. By using this composition, a mesoporous layer can be obtained having a low dielectric constant (68ᵣ<2.6) and a high stability, even in humid conditions. Measurements have shown that at varying degrees of humidity, including relative humidity levels in excess of 80%, the refractive index changes hardly, if at all. This means, inter alia, that a mesoporous layer can be obtained whose porosity is higher than that of a mesoporous layer of pure TEOS. As will be understood by persons skilled in the art, a low dielectric constant is very important in the manufacture of transistors having comparatively small channel lengths. Said reduction of the channel length to 100 nm or less causes the RC delay to become one of the factors that determine the addressing speed of transistors. At the same time, the resistance increases owing to the smaller width of metal tracks. Also the capacitance tends to increase owing to the smaller distance between metal lines. As a result, the use of layers whose dielectric constant is lower than that of SiO₂ (68ᵣ=4.2) is necessary.

For the surfactant use can be made of cationic, anionic and non-ionic surfactants. Examples are, inter alia, cetyltrimethylammoniumbromide and cetyltrimethylammoniumchloride, triblock copolymers of polyethylene oxide, polypropylene oxide, polyethylene oxide ethers, such as polyoxyethylene (10) stearyl ether.

Favorable results are achieved using a cationic surfactant in combination with a molar ratio between said surfactant and the totality of alkoxysilanes in excess of 0.1:1. In this manner, layers can be achieved having a relative dielectric constant below 2.5. Unlike mesoporous layers prepared from pure TEOS, the mesoporous layers manufactured as described above remain stable, even if the composition comprises a high surfactant content. The resultant layers have a porosity above 50% and were found to be of good quality. Although heating is by no means necessary, it can be carried out under reducing conditions, for example in an atmosphere of nitrogen and hydrogen. It has been found, as is shown in Table 2, that heating in these reducing conditions at increasing porosities results in a reduction of the dielectric constant.

Favorable results have also been achieved using a triblock copolymer comprising polyethylene oxide, polypropylene oxide and polyethylene oxide as the blocks serving as the surfactant. An example of such a surfactant is known by the name of Pluronic F127. Low concentrations of this surfactant in the composition already lead to a mesoporous layer having a high porosity and a low dielectric constant.

A composition comprising a TEOS, an ASAS, an ionic surfactant and a solvent is known from Balkenende et. al., Book of Abstracts, Conference on nanostructured materials made from self-assembled molecules and particles, Hindas (Sweden), 2001. In the known composition, the alkyl or aryl-substituted alkoxysilane is phenyltriethoxysilane (PhTES). The ionic surfactant is cetyltrimethylammoniumbromide and the solvent is a 80/20 mixture of ethanol and water that has been acidified. The molar ratio between TEOS and PhTES is 3:1. The molar ratio between the surfactant and the totality of alkoxysilane, i.e. TEOS+PhTES, is 0.1:1. The composition is applied to a substrate and heated to 350° C. This results in a mesoporous layer having a porosity of approximately 45%.

A second object of the invention is to provide a composition enabling a mesoporous layer to be manufactured having a relative dielectric constant below 2.6, which dielectric constant is essentially insensitive to the degree of air humidity.

It is a third object of the invention to provide a method of the type mentioned in the opening paragraph, by means of which a mesoporous layer having a relative dielectric constant below 2.6 can be obtained, which dielectric constant is essentially insensitive to the degree of air humidity.

Said second object is achieved in that the molar ratio between the tetra-alkoxysilane and the aryl-substituted or alkyl-substituted alkoxysilane is below 3:2.

It has been found that the composition in accordance with the invention enables a layer having the desired properties to be obtained. In addition, the compositions in accordance with the invention can be used to manufacture mesoporous layers having a higher porosity. The layers obtained have the advantage, as compared to the layers known from WO-A-00/39028, that they are stable without a dehydroxylation aftertreatment. In particular, it has also been found that the layers formed by means of the composition in accordance with the invention have a good mechanical stability, which could not be expected on the basis of the known composition.

In all cases it applies that such a composition, in which the molar ratio between TEOS and ASAS is above 3:1, does not have a low and stable dielectric constant. In a particularly favorable embodiment, the ASAS used is methyltrimethoxysilane.

For the surfactant use can be made of cationic, anionic and non-ionic surfactants. Examples are, inter alia, cetyltrimethylammoniumbromide (CTAB) and cetyltrimethylammoniumchloride, triblock copolymers of polyethylene oxide, polypropylene oxide, polyethylene oxide ethers, such as polyoxyethylene (10) stearyl ether. Preferably, the surfactant is present in concentrations above 0.15 g per gram of alkoxysilane. In the case of a surfactant like CTAB, this means that the concentration is in excess of 0.1 mol per mol of alkoxysilane. This leads to a substantial increase in porosity and reduction of the dielectric constant. Nevertheless, the mechanical stability is surprisingly good.

The third object is achieved in that the molar ratio between TEOS and ASAS is 3:1 at the most. In a favorable embodiment of the method in accordance with the invention, the composition in accordance with the invention is used. Preferably, the removal of the solvent and the surfactant, while forming the mesoporous layer, takes place by first drying the liquid layer and subsequently heating it to a temperature in the range from 350 to 450° C.

These and other aspects of the electronic device, the composition and the method in accordance with the invention will be explained in greater detail with reference to a drawing and Tables, in which:

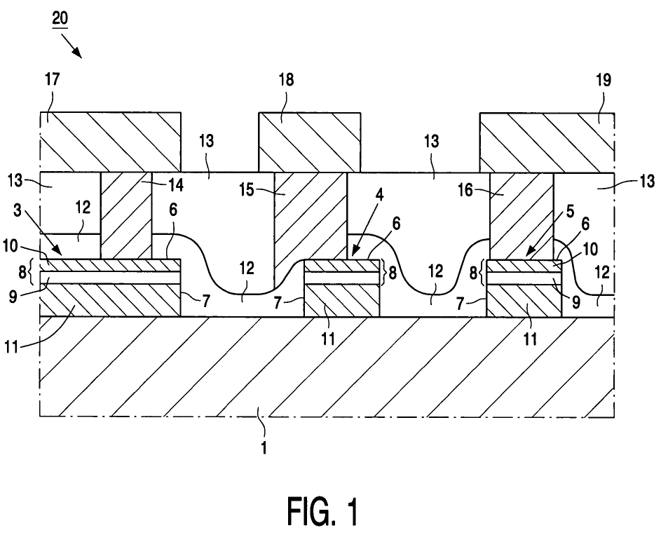

FIG. 1 is a diagrammatic, cross-sectional view of the electronic device;

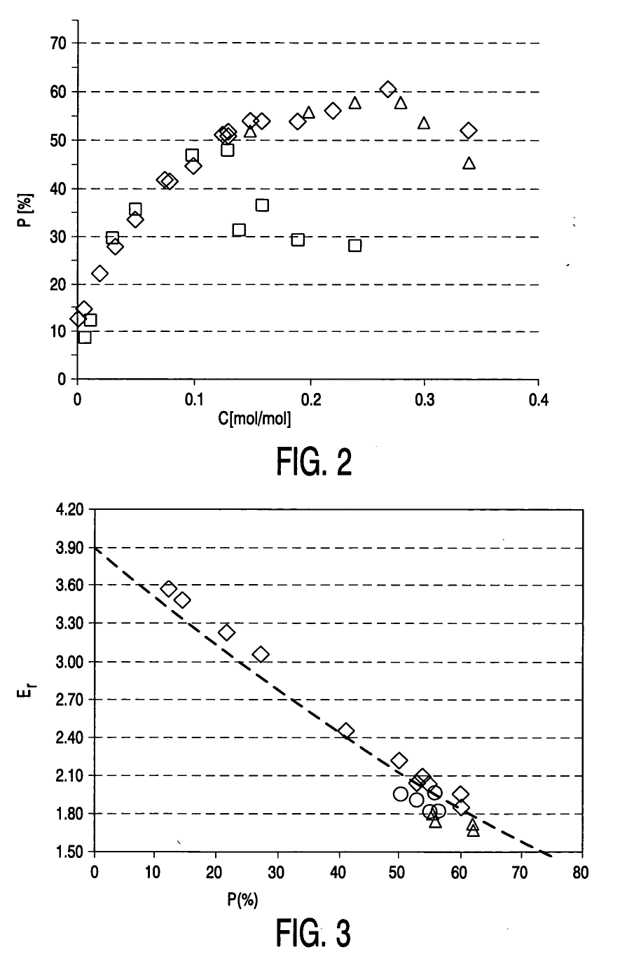

FIG. 2 shows the influence of the surfactant concentration in the composition on the porosity of the layer obtained;

FIG. 3 shows a relation between the dielectric constant and the porosity;

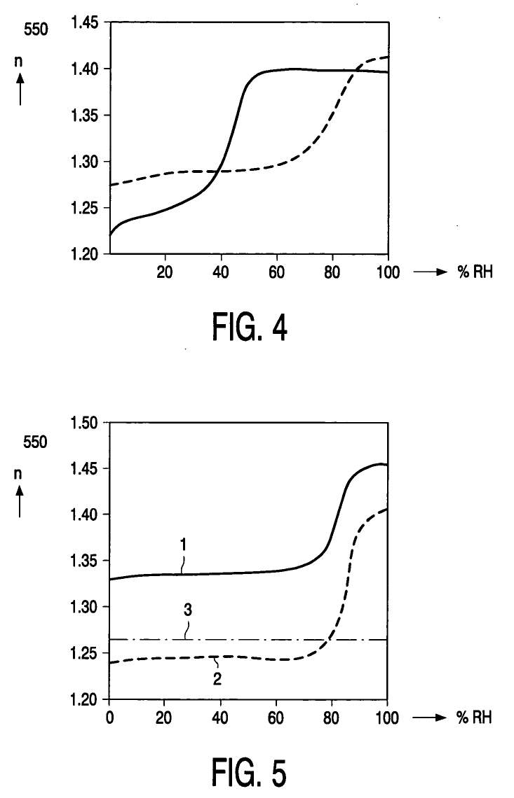

FIG. 4 shows the influence of the degree of humidity of the environment on the refractive index of mesoporous layers formed in accordance with known methods;

FIG. 5 shows the influence of the degree of humidity of the environment on the refractive index of mesoporous layers in the device;

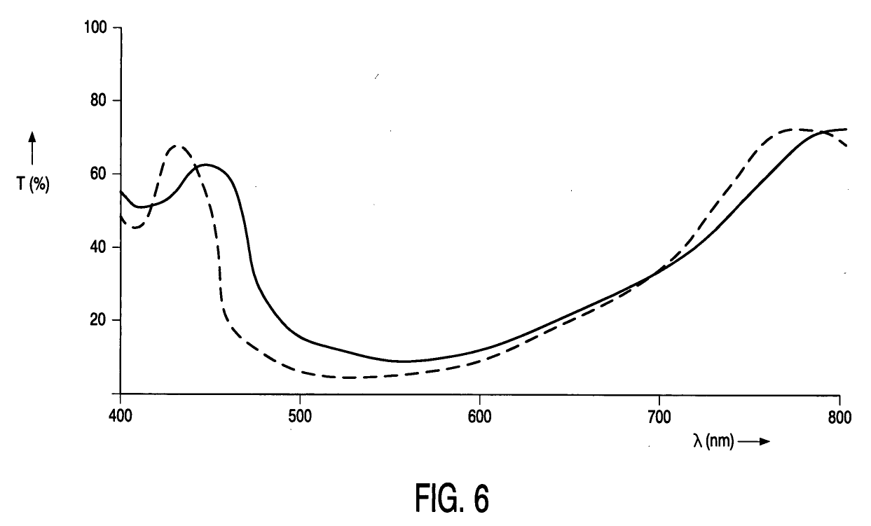

FIG. 6 shows the reflection of an embodiment of the device as a function of the wavelength at different degrees of air humidity,

Table 1 shows embodiments of compositions by means of which mesoporous layers can be formed;

Table 2 shows properties of the layer obtained by using the embodiments 1-6 of Table 1;

Table 3 shows properties of the layer obtained by using the embodiments 7-12 of Table 1;

Table 4 shows further compositions by means of which mesoporous layers can be obtained, as well as the dielectric constant and the porosity of the mesoporous layers;

Table 5 shows the hardness and the Young's modulus for different compositions; and

Table 6 shows the sensitivity of mesoporous layers based on different compositions to the degree of humidity.

FIG. 1 is a diagrammatic cross-sectional view of the electronic device, which is not drawn to scale. The device shown in this example is a semiconductor device 20. Said semiconductor device 20 comprises a semiconductor substrate 1 provided with conductors 3, 4, 5 at a surface 2. The conductors 3, 4, 5 each have an upper surface 6 and side faces 7. It is noted that it is possible that only one conductor is provided, although the invention is described in the context of three conductors 3, 4, 5 and three vias 14, 15, 16. Customarily, however, the semiconductor device comprises a large number of conductors and vias. Although they are shown as one element, the semiconductor substrate 1 customarily comprises a plurality of layers formed on, for example, a semiconductor body formed, for example, from silicon. The conductors 3, 4, 5 can fulfill various functions. It is possible that the conductors 3, 4, 5 are the gate electrodes of a metal-oxide-semiconductor field effect transistor (MOSFET) or a thin-film transistor (TFT). Alternatively, the conductors 3, 4, 5 can form the bases or emitters of a bipolar device or a BiCMOS device. Furthermore, the conductors 3, 4, 5 may be part of a metal layer of a multilayer interconnect structure.

The conductors 3, 4, 5 are composed of a metal portion 11 covered by a top layer 8 that serves as an anti-reflective coating. In this example, the top layer 8 is a double layer of a layer of titanium 9 and a layer of titanium nitride 10. The conductors 3, 4, 5 are formed in accordance with conventional process steps. Subsequently, an etch stop layer 12 of silicon carbide is provided at the upper surface 6 and the side faces 7 of the conductors 3, 4, 5 and also on the uncovered part of the surface 2 of the semiconductor substrate 1.

The etch stop layer 12 is provided with a composition of TEOS, ASAS, a surfactant and a solvent. Specific compositions are listed in Table 1. For the solvent use is made, in this case, of a mixture of alcohol, water and a small amount of acid. Suitable alcohols include, inter alia, methanol, ethanol, propanol and butanol. After drying and heating at 400° C., the mesoporous layer 13 is formed. It has been found that the thickness of the layer formed depends on the number of revolutions during spin coating, the viscosity of the composition and the degree of dilution of the composition. If cetyltrimethylammoniumbromide (CTAB) is used as the surfactant, the pore size is 2-3 nm; if Pluronic F127 is used as the surfactant, the pore size is 7-8 nm. Measurements using X-ray diffraction and SEM equipment show that the pore size is substantially uniform.

The properties of this layer depend on the composition, as listed in Table 2. Conductors 17, 18, 19, preferably of copper, are present on the mesoporous layer 13. To preclude undesirable diffusion of ions and particles, preferably, a barrier layer, not shown, is applied to the mesoporous layer 13.

To pattern the mesoporous layer 13, a photoresist (not shown) is provided. This photoresist is subsequently exposed in accordance with a desired pattern and developed. As a result, a photoresist mask is obtained having openings at the locations where vias 14, 15, 16 are formed during filling with metal. The mesoporous layer 13 is etched using a CVD treatment comprising, at a pressure of 23.3 Pa (175 mTorr), 500 sccm Ar/50 sccm CF₄ and 20 sccm CHF₃. If the thickness of the mesoporous layer 13 over the surface 2 of the semiconductor body 1 is not uniform, certain vias can be subjected to a wet-chemical treatment for a comparatively long period of time. To preclude reactions between the etchants and the metal conductors 3, 4, 5, and in connection with the occurrence of slightly misaligned vias, such as via 15, the etch stop layer 12 is applied. This etch stop layer 12 is removed at the location of the vias 14, 15, 16 to be formed by means of, for example, a fluorocarbon in a dry, anisotropic etching treatment. Subsequently, conductive material, such as aluminum, copper or tungsten is provided and the vias 14, 15, 16 are formed. Preferably, an adhesive layer and/or a barrier layer is deposited prior to the deposition of the conductive material. Next, the conductive material is polished by means of a conventional CMP treatment.

### EXAMPLE 1

A composition of tetraethoxyorthosilicate (TEOS), methyltrimethoxysilane (MTMS), water and ethanol, which is acidified with HCl, is formed while stirring. The molar ratios of TEOS:MTMS:H₂O:ethanol:HCl are 0.5:0.5:1:3:5.10⁻⁵. This composition was heated to 60° C. for 90 minutes. Water, ethanol, HCl and cetyltrimethylammoniumbromide (CTAB) were added to this pre-treated composition to obtain a molar ratio of TEOS:MTMS:H₂O:ethanol:HCl:CTAB of 0.5:0.5:7.5:20:0.006:0.10. The composition was stirred for three days at room temperature. Subsequently, the composition is provided by means of spin coating at 1000 rpm for 1 minute in a KarlSuss CT62 spin coater. The layer is dried at 130° C. for 10 minutes on a hot plate and subsequently heated to 400° C. for 1 hour in air. In this manner a mesoporous layer having a thickness of 200-400 nm is obtained having a relative dielectric constant of 2.4 and a porosity of 44%, as listed in Table 2.

In this case, the dielectric constant is measured by means of a mercury probe (type Hg-612 from MSI electronics) at a frequency of 1 MHz. The porosity is determined in at least one of the two following ways known to persons skilled in the art: on the basis of the refractive index and by means of a layer thickness measurement and RBS. The refractive index is determined through ellipsometry using a VASE ellipsometer VB-250, JA Woolam Co, Inc. From this value the porosity is determined via a Bruggeman effective medium approximation with a depolarization factor of 0.33.

### EXAMPLE 2

A composition of TEOS, MTMS, water, ethanol, HCl and CTAB is prepared, in which the amount of surfactant is increased, as compared to example 1, to 0.22. The composition is treated in the manner described in example 1. This leads to a layer having a relative dielectric constant of 2.3 and a porosity of 56%.

### EXAMPLE 3

The composition of example 2 is stirred for three days at room temperature. Subsequently, the composition is provided by means of spin coating at 1000 rpm for 1 minute in a KarlSuss CT62 spin coater. The layer is dried at 130 ° C. for 10 minutes and subsequently heated to 400° C. for 1 hour in a gas mixture comprising 93 vol. % N₂ and 7 vol. % H₂. A layer having a relative dielectric constant of 1.9 is obtained.

### EXAMPLE 4

A composition of TEOS, MTMS, water, ethanol and surfactant is prepared, wherein the quantity of MTMS is increased, as compared to example 1, to TEOS:MTMS=0.4:0.6. In this case, for the surfactant use is made of Brij76 (polyoxyethylene (10) stearyl ether) in a concentration of 0.13 mol/mol siloxane. The composition is treated in the manner described in example 1. This leads to a mesoporous layer having a relative dielectric constant of 1.7 and a porosity of 62.4%.

### EXAMPLE5

### Not in Accordance with the Invention

A composition is prepared of TEOS, water, ethanol, HCl and CTAB in the ratio indicated in Table 1. The composition is stirred at room temperature for three days. Subsequently the composition is applied by means of spin coating at 1000 rpm for 1 minute in a KarlSuss CT62 spincoater. The layer is dried at 130° C. for 10 minutes and subsequently heated to 400° C. in air for 1 hour. This leads to a mesoporous layer having a layer thickness of 200-400 nm and a relative dielectric constant above 6. The layer contains moisture, which is corroborated in ellipsometric measurements, the air humidity degree being varied.

| no | TEOS | ASAS | surfactant | HCl | H₂O | EtOH | application | heating |
|---|---|---|---|---|---|---|---|---|
| 1 | 0.75 | MTMS, | CTAB, | 0.004 | 5 | 20 | dipping | 1 hour at 400° C. |
| | | 0.25 | 0.08-0.14 | | | | | in air |
| 2 | 0.75 | PhTES, | CTAB, | 0.004 | 5 | 20 | Spin | 1 hour at 350° C. |
| | | 0.25 | 0.1 | | | | coating | in air |
| 3 | 0.5 | MTMS, | CTAB | 0.006 | 7.5 | 20 | Spin | 1 hour at 400° C. |
| | | 0.5 | 0.10-0.22 | | | | coating | in air |
| 4 | 0.5 | MTMS, | CTAB | 0.006 | 7.5 | 20 | Spin | 1 hour at 400° C. |
| | | 0.5 | 0.10-0.22 | | | | coating | in 7% H₂ |
| | | | | | | | | in N₂ |
| 5* | 1.0 | 0 | CTAB | 0.006 | 7.5 | 20 | Spin | 1 hour at 400° C. |
| | | | 0.10-0.24 | | | | coating | in air |
| 6 | 0.5 | MTMS, | F127, | 0.004 | 5 | 20 | dipping | 1 hour at 400° C. |
| | | 0.5 | 0.0052 | | | | | in air |
| 7 | 0.5 | MTMS, 0.5 | F127, | 0.004 | 5 | 20 | Spin | 1 hour at 400° C. |
| | | | 0.006 | | | | coating | in air |
| 8 | 0.5 | MTMS, | F127, | 0.004 | 5 | 10 | Spin | 1 hour at 400° C. |
| | | 0.5 | 0.006 | | | | coating | in air |
| 9 | 0.5 | MTMS, | CTAB, | 0.004 | 5 | 20 | Spin | 1 hour at 400° C. |
| | | 0.5 | 0.10 | | | | coating | in air |
| 10 | 0.5 | MTMS, | Brij 76, | 0.004 | 5 | 20 | Spin | 1 hour at 400° C. |
| | | 0.5 | 0.14 | | | | coating | in air |
| 11 | 0.67 | DMDES, | CTAB, | 0.004 | 5 | 20 | Spin | 1 hour at 400° C. |
| | | 0.33 | 0.18 | | | | coating | in air |
| 12 | 0.67 | DMDES, | CTAB, | 0.004 | 5 | 20 | Spin | 1 hour at 400° C. |
| | | 0.33 | 0.18 | | | | coating | in 7% H₂, |
| | | | | | | | | in N₂ |

*not in accordance with the invention

Table 1, compositions, way of applying and heating. The figures listed indicate the molar ratios.

TEOS=tetraethoxyorthosilicate

CTAB=cetyltrimethylammoniumbromide

MTMS=methyltrimethoxysilane

PhTES=phenyltriethoxysilane

F127=Pluronic F127, a triblock polymer comprising polyethylene oxide, polypropylene oxide and polyethylene oxide as the blocks; Brij76=polyoxyethylene (10) stearyl ether, C₁₈H₃₇(OCH₂CH₂)nOH, n≈10

DMDES=dimethyldiethoxysilane

| | Surfactant | | | |
|---|---|---|---|---|
| no | concentration | porosity | nᵢ | εᵣ |
| 1 | 0.08 | 45% | 1.25 | 3.9 |
| | 0.10 | 49% | 1.23 | 3.1 |
| | 0.12 | 54% | 1.21 | 3.3 |
| | 0.14 | 53% | 1.21 | 3.3 |
| 2 | 0.1 | 45% | 1.34 | 2.6 |
| | | | (<50% RH), | |
| | | | 1.45 | |
| | | | (>70% RH) | |
| 3 | 0.10 | 44% | 1.25 | 2.4 |
| | 0.13 | 50% | 1.23 | 2.3 |
| | 0.16 | 53% | 1.21 | 2.2 |
| | 0.19 | 53% | 1.21 | 2.2 |
| | 0.22 | 56% | 1.20 | 2.3 |
| 4 | 0.10 | 45% | 1.25 | 2.5 |
| | 0.16 | 54% | 1.20 | 2.0 |
| | 0.22 | 56% | 1.19 | 1.9 |
| 5* | 0.10 | 46% | 1.24 | >6 |
| | 0.13 | 47% | 1.24 | |
| | 0.16 | 36% | 1.29 | |
| | 0.19 | 29% | 1.32 | |
| | 0.24 | 28% | 1.33 | |
| 6 | F127/ | 54% | 1.20 | 1.8 |
| | 0.0052 | | | |

Table 2—porosity, refractive index nᵢ and relative dielectric constant εᵣ of the mesoporous layers prepared using the compositions 1-6 with varying quantities of surfactant. Unless indicated otherwise, the surfactant used is CTAB.

| | rpm during | layer thickness | | | |
|---|---|---|---|---|---|
| no | spin coating | (nm) | porosity | n₁ | εᵣ |
| 7 | 1000 rpm | 692 | 54% | 1.20 | |
| | 750 rpm | 851 | 57% | 1.19 | |
| | 500 rpm | 1030 | 57% | 1.19 | |
| 8 | 1000 rpm | 1545 | 59% | 1.20 | |
| | 750 rpm | 1802 | 60% | 1.19 | |
| 9 | 1000 rpm | 409 | 46% | 1.24 | |
| | 750 rpm | 473 | 46% | 1.24 | |
| | 500 rpm | 568 | 46% | 1.24 | |
| 10 | 1000 rpm | 494 | 59% | 1.18 | 1.8 |
| 11 | 1000 rpm | 441 | 53% | 1.21 | 2.6 |
| 12 | 1000 rpm | 438 | 51% | 1.22 | 2.5 |

Table 3 —layer thickness, porosity, refractive index nᵢ and relative dielectric constant εᵣ of the mesoporous layers prepared using the compositions 7-12 at a varying number of revolutions during spin coating.

Table 4 shows compositions wherein the ASAS content is higher than in the compositions listed in Table 1. The abbreviations used are identical to those used in Table 1. Mesoporous layers are prepared by applying the compositions to a substrate by means of spin coating and subsequently heating these compositions in air at 400° C. for 1 hour. Table 4 also shows the porosity and the relative dielectric constant εᵣ of the mesoporous layers.

TABLE 4

| no | TEOS | ASAS | surfactant | HCl | H₂O | EtOH | porosity | εᵣ |
|---|---|---|---|---|---|---|---|---|
| 13 | 0.4 | MTMS, 0.6 | CTAB, 0.10 | 0.004 | 5 | 20 | 45% | |
| 14 | 0.4 | MTMS, 0.6 | CTAB, 0.27 | 0.004 | 5 | 20 | 52% | 1.8 |
| 15 | 0.4 | MTMS, 0.6 | Brij76, | 0.004 | 5 | 20 | 60% | 1.7 |
| | | | 0.13-0.16 | | | | | |
| 16 | 0.4 | MTMS, 0.6 | F127, 0.007 | 0.004 | 5 | 10 | 56% | 1.75 |
| 17 | 0.25 | MTMS, 0.75 | CTAB, 0.1 | 0.004 | 5 | 20 | 42% | |
| 18 | 0.1 | MTMS, 0.9 | CTAB, 0.1 | 0.004 | 5 | 20 | 40% | |

FIG. 2 shows the porosity P of mesoporous layers as a function of the surfactant concentration C. The concentration is given in mol per mol of siloxane (total amount of TEOS and ASAS). For the surfactant use is made of CTAB. The measurements indicated by means of squares relate to a mesoporous layer in accordance with the state of the art, which is obtained using a composition comprising TEOS. The measurements indicated by means of diamonds relate to a mesoporous layer in accordance with the invention, which is obtained using a composition of TEOS and MTMS in a molar ratio of 1:1. The measurements indicated by means of triangles relate to a mesoporous layer in accordance with the invention, which is obtained using a composition of TEOS and MTMS in a molar ratio of 2:3.

At CTAB concentrations below 0.1, the porosity increases as the concentration increases, and there is no difference between a layer based on a composition of pure TEOS and a layer prepared by means of the method in accordance with the invention. At a CTAB concentration of 0.1 (mol/mol) the porosity is 40-45%. At CTAB concentrations above 0.1 (mol/mol) the porosity of a mesoporous layer based on pure TEOS no longer increases but instead decreases to approximately 30%. If, however, compositions in accordance with the invention are used, mesoporous layers having a higher porosity up to 60% are obtained. At CTAB concentrations above 0.27 (mol/mol) a slight decrease of the porosity to 45-50% is observed.

FIG. 3 shows the relative dielectric constant εᵣ as a function of the porosity P. The measurements indicated by means of diamonds relate to a mesoporous layer in accordance with the invention, which is obtained using a composition of TEOS and MTMS in a molar ratio of 1: 1, wherein CTAB is used as the surfactant. The measurements indicated by means of circles relate to a mesoporous layer in accordance with the invention, which is obtained using a composition of TEOS and MTMS in a molar ratio of 2:3, wherein CTAB is used as the surfactant. The measurements indicated by means of triangles relate to a mesoporous layer in accordance with the invention, which is obtained using a composition of TEOS and MTMS in a molar ratio of 2:3, wherein Brij76 is used as the surfactant. The line that extends through the measurements carried out on layers based on compositions comprising TEOS:MTMS=1:1 shows that a linear relationship exists between dielectric constant and porosity. The measurements carried out on layers based on compositions comrising TEOS:MTMS=2:3 are situated slightly to the left of the line that relates to TEOS:MTMS=1:1. This indicates that the same dielectric constant is achieved already at a lower porosity.

Table 5 shows the porosity, the hardness and the Young's modulus for a number of mesoporous layers. Said mesoporous layers are prepared using the compositions listeded in Tables 1 and 4, with the exception of layers 19 and 20. Said mesoporous layers are known from S. Yang et.al., Chem. Mater. 14(2002), 369-374. Said mesoporous layers are made from poly(methylsilsesquioxane) (MSQ), wherein triblock polymers, i.e. poly(ethylene oxide-b-propylene oxide-b-ethylene oxide), are used. These mesoporous layers are prepared using a composition of MSQ precursors having an average molecular weight M_{r,n} of 1668 g/mol. The composition is a 30% solution in n-butanol and further comprises said triblock polymer. After filtration, the composition was applied to a substrate, whereafter the liquid layer was dried at 120° C. and heated at 500° C. It is noted that Yang et al. used a composition with an MSQ precursor, which is a polymer already, as the starting composition. In the invention, the starting composition comprises TEOS and an ASAS, which are monomers.

TABLE 5
hardness and Young's modulus for various mesoporous layers.

| | TEOS: | | | hardness | Young's |
|---|---|---|---|---|---|
| no | MTMS | surfactant | porosity | (GPa) | modulus (GPa) |
| 5* | 1:0 | CTAB, 0.1 | 49% | 0.8 | 12-17 |
| 1 | 3:1 | CTAB, 0.1 | 49% | 0.7 | 8 |
| 3 | 1:1 | CTAB, 0.1 | 45% | 0.8 | 4.5 |
| 13 | 2:3 | CTAB, 0.1 | 45% | 0.8 | 5.4 |
| 14 | 2:3 | CTAB, 0.27 | 52% | 0.5 | 3.0 |
| 15 | 2:3 | Brij76, 0.16 | 60% | 0.5 | 3.2 |
| 16 | 2:3 | F127, 0.007 | 56% | 0.36 | 2.0 |
| 17 | 1:3 | CTAB, 0.1 | 42% | 0.6 | 3.5 |
| 18 | 1:9 | CTAB, 0.1 | 40% | 0.6 | 3.5 |
| 19* | Not | triblock F88 | 40% | 0.28 | 1.3 |
| | applicable | | | | |
| 20* | Not | triblock F88 | 50% | 0.16 | 0.6 |
| | applicable | | | | |

*= not in accordance with the invention

The values listed in Table 5 show that the hardness of the mesoporous layer in accordance with the invention decreases only slightly as the TEOS:MTMS ratio decreases if use is made of a constant type and concentration of the surfactant. Only the use of higher concentrations of the surfactant CTAB or of a different surfactant causes the porosity to increase and the hardness to decrease. Said hardness levels and Young's moduli, however, are still twice or thrice as high as the hardness values disclosed in the publication by Yang et.al. Therefore, it can be concluded that the mechanical strength of these layers is sufficient to withstand chemical-mechanical polishing (CMP) during the manufacture of integrated circuits.

Table 6 shows the porosity as a function of the air humidity for mesoporous layers based on compositions having different molar ratios of TEOS:MTMS. It can be concluded from the Table that by using a composition comprising TEOS:MTMS<3:2, a mesoporous layer is obtained which is hydrophobic also under conditions where the air humidity is high. As regards the ratio TEOS:MTMS=3:1, it has been found that humidification, and hence a reduction of the porosity, takes place only at degrees of humidity above 80%. Desorption of the adsorbed water is accompanied by a hysteresis effect. During a subsequent increase of the degree of air humidity adsorption already takes place from a degree of relative air humidity of approximately 40%. If the degree of humidity does not exceed 60%, humidification does not take place and the porosity level remains high, resulting in a low refractive index and a low dielectric constant.

| composition | | | low degree | | high degree | |
|---|---|---|---|---|---|---|
| (mol) | | | of humidity | | of humidity | |
| TEOS | MTMS | CTAB | % RH | porosity | % RH | porosity |
| 1.0 | 0 | 0.10 | 2 | 45% | 50* | 12% |
| | | | | | 35** | |
| 0.75 | 0.25 | 0.10 | 2-70* | 45% | 85* | 15% |
| 0.6 | 0.4 | 0.15 | 1.6 | 54.3% | 92 | 15.2% |
| 0.55 | 0.45 | 0.15 | 2.6 | 51.9% | 88.7 | 51% |
| 0.50 | 0.50 | 0.15 | 2.5 | 53.2% | 82 | 52.7% |
| 0.40 | 0.60 | 0.15 | 2 | 51.1% | 76 | 50.7% |

*at the first adsorption
**at desorption

Table 6 —the sensitivity to the degree of humidity of mesoporous layers in accordance with the invention as a function of the composition used to prepare the layer. The composition further comprises the constituents listed in Table 1. The mesoporous layers are prepared in accordance with example 1. %RH=relative degree of humidity.

FIG. 4 shows the influence of the degree of air humidity on the refractive index of various mesoporous layers prepared in accordance with known methods. A change of the refractive index can be attributed to water adsorption in the pores of the layer. This is accompanied by an increase of the dielectric constant. Since the diameter of the pores is small and the mesoporous layer is covered by a subsequent layer in the device, water adsorption in a mesoporous layer in a semiconductor device must be considered to be irreversible in practice. The refractive index n⁵⁵⁰ is measured in accordance with the above-mentioned method at a wavelength of 550 nm.

The solid line shown in FIG. 4 relates to a mesoporous layer of pure tetraethoxyorthosilicate. At a degree of humidity of 0%, corresponding to anhydrous air, the refractive index is 1.22. At a degree of humidity of 30%, the refractive index is 1.26 already, and at 50%, the refractive index has increased to 1.40.

The dashed line in FIG. 4 relates to a mesoporous layer of pure teatraethoxyorthosilicate that, after the provision of the mesoporous layer, has been treated with trimethylchlorosilane during drying. At a degree of humidity of 0%, the layer has a refractive index of 1.27. At a degree of humidity of 60%, the refractive index is 1.30, and at a degree of humidity of 80%, the refractive index is 1.40. The relative dielectric constant is above 6 at degrees of humidity in excess of 30%.

In both cases the refractive index exhibits a hysteresis effect. In the case of the TEOS layer that has not been subjected to an aftertreatment, this hysteresis effect leads to a refractive index of 1.38 at a degree of humidity of 35%. In the case of the TEOS layer that has been subjected to an aftertreatment, hysteresis is such that the refractive index is 1.40 at a degree of humidity of 60% and 1.30 at a degree of humidity of 40%. The results indicate that a substantial degree of water adsorption has taken place under conditions occurring in industrial manufacturing processes.

FIG. 5 shows the influence of the degree of air humidity on the refractive index of various mesoporous layers forming part of electronic devices in accordance with the invention.

The solid line (1) relates to a layer prepared from a composition comprising tetraethoxyorthosilicate and phenyltriethoxysilane in a molar ratio of 3:1. At a degree of humidity of 0%, the refractive index is 1.33, and at an air humidity of 50%, the refractive index is 1.335. At air humidity levels of 60% and higher the refractive index increases, and at a degree of humidity of 90% the refractive index is 1.45 If the degree of humidity of 90% is reduced, a hysteresis effect occurs. The relative dielectric constant is 2.6.

The dashed line (2) relates to a layer prepared from a composition comprising tetraethoxyorthosilicate and methyltrimethoxysilane in a molar ratio of 0.75:0.25. The concentration of the surfactant CTAB is 0.10. At a degree of humidity of 0%, the refractive index is 1.23, which value remains the same at an air humidity level of 50%. At an air humidity level of 70% and higher, the refractive index increases. If the degree of humidity of 90% is reduced, a hysteresis effect occurs.

The dash-dot line (3) relates to a layer prepared from a composition comprising tetraethoxyorthosilicate and methyltrimethoxysilane in a molar ratio of 0.5:0.5. The concentration of the surfactant CTAB is 0.10. The refractive index of this layer is 1.25, independent of the air humidity level. The relative dielectric constant is 2.4.

FIG. 6 relates to an embodiment of the device wherein a substrate of silicon is provided with a stack of layers comprising alternately a layer of TiO₂ and a layer of porous aryl-substituted or alkyl-substituted SiO₂. Said stack of layers comprises a total of several layers having a thickness as indicated hereinbelow. The empirical formula of said alkyl-substituted SiO₂ is SiO_{1.875}(Me)_{0.125}. Said alkyl-substituted SiO₂ is manufactured using a composition comprising TEOS and MTMS in a molar ratio of 3:1, wherein Pluronic F127 is used as the surfactant.

| layer no. | material | thickness (nm) | n⁵⁵⁰ |
|---|---|---|---|
| 1 | TiO2 | 53 | 2.245 |
| 2 | SiOxMey | 101 | 1.237 |
| 3 | TiO2 | 65 | 2.172 |
| 4 | SiOxMey | 89 | 1.251 |
| 5 | TiO2 | 65 | 2.152 |
| 6 | SiOxMey | 103 | 1.252 |
| 7 | TiO2 | 65 | 2.116 |

In FIG. 6, the transmission T (in %) of the stack of layers is indicated as a function of the wavelength λ for two different degrees of air humidity. The solid line relates to a degree of air humidity of approximately 50% and is measured in air. The dashed line relates to a degree of air humidity of less than 2% and is measured in N₂. The stack of layers can be used, for example, as an interference stack, in which case the filter characteristic can be controlled by means of air humidity or temperature. The stack of layers can also be used for optical storage of data, or for display screens and sensors. Inter alia by varying the composition of the alkyl-substituted SiO₂, the high-low transmission transition can be set to a desired relative air humidity or saturation vapor pressure between 10 and 90%. Said transition can also be influenced by means of the pore size in the layer. This pore size depends on the surfactant used. The degree to which the transmission at a first degree of air humidity differs from that at a second degree of air humidity depends on the wavelength of the light coupled-in. This means that the change in relative air humidity can be observed as a shift of the reflected light. Such a stack can also be obtained using different mesoporous layers, such as mesoporous TiO₂ layers.

The above-mentioned porosities in the range from 40 to at least 60%, the very low dielectric constant of 2.0 and less, and the good mechanical stability causes the mesoporous layer that can be obtained by means of the method in accordance with the invention to be very suitable as an intermetallic or intrametallic dielectric in a semiconductor device, particularly in an interconnect structure of an integrated circuit. This also applies because a suitable choice of ASAS enables thermal stability to temperatures above 400° C. to be obtained and because the mesoporous layer has a dielectric constant that is comparatively or entirely insensitive to the degree of air humidity of the atmosphere. In addition, the pore size is uniform and below 10 nm, which precludes diffusion of metal ions and other atoms, molecules or particles.

1. An electronic device comprising:
a substrate provided on one side with a mesoporous layer containing silica, which layer can be obtained by
applying a liquid layer of a composition comprising tetra-alkoxysilane, aryl-substituted or alkyl-substituted alkoxysilane, a surfactant and a solvent onto a substrate, wherein the molar ratio between the tetra-alkoxysilane and the aryl-substituted or alkyl-substituted alkoxysilane is 3:1 at the most; and
by removing the surfactant and the solvent from the liquid layer, thereby forming the hydrophobic, mesoporous layer.

2. An electronic device as recited in claim 1, wherein a first and a second conductor are present which are electrically insulated from each other by the mesoporous layer; and
the mesoporous layer has a relative dielectric constant below 3.0.

3. An electronic device as recited in claim 2, wherein the mesoporous layer has a porosity above 45%.

4. An electronic device as recited in claim 1, wherein the aryl-substituted or alkyl-substituted alkoxysilane is selected among the group formed by C₁-C₃-alkyl and phenyltrialkoxysilanes and fluoridized analogues thereof, which alkoxy group is selected among the group formed by methoxy, ethoxy, propoxy and butoxy.

5. An electronic device as recited in claim 4, wherein the aryl-substituted or alkyl-substituted alkoxysilane is methyltrimethoxysilane (MTMS).

6. A composition comprising:
tetra-alkoxysilane, aryl-substituted or alkyl-substituted alkoxysilane,
a surfactant and a solvent, wherein the molar ratio between the tetra-alkoxysilane and the aryl-substituted or alkyl-substituted alkoxysilane is below 3:2.

7. A composition as recited in claim 6, wherein the weight ratio of the surfactant to the total amount of alkoxysilanes is in excess of 0.15:1.

8. A composition as recited in claim 6, wherein the aryl-substituted or alkyl-substituted alkoxysilane is selected among the group consisting of C₁-C₃-alkyltrialkoxysilanes, which alkoxy group is selected among the group consisting of methoxy, ethoxy, propoxy and butoxy.

9. A method of preparing a mesoporous layer comprising:
the provision of a liquid layer of a composition comprising tetra-alkoxysilane, aryl-substituted or alkyl-substituted alkoxysilane, a surfactant and a solvent onto a substrate, wherein the molar ratio between the tetra-alkoxysilane and the aryl-substituted or alkyl-substituted alkoxysilane is 3:1 at most; and
removing the surfactant and the solvent from the liquid layer, thereby forming the hydrophobic mesoporous layer.

10. A method as recited in claim 9, wherein the composition that is applied comprises:
tetra-alkoxysilane, aryl-substituted or alkyl-substituted alkoxysilane,
a surfactant and a solvent, wherein the molar ratio between the tetra-alkoxysilane and the aryl-substituted or alkyl-substituted alkoxysilane is below 3:2.

11. The method of claim 10 wherein the composition that is applied further comprises,
the weight ratio of the surfactant to the total amount of alkoxysilanes is in excess of 0.15:1.

12. The method of claim 10 wherein the composition that is applied further comprises,
the aryl-substituted or alkyl-substituted alkoxysilane is selected among the group consisting of C₁-C₃-alkyltrialkoxysilanes, which alkoxy group is selected among the group consisting of methoxy, ethoxy, propoxy and butoxy.
